(19) United States
(12) Patent Application Publication
(10) Pub. No.: US 2026/0206623 A1
(43) Pub. Date: Jul. 16, 2026

(54) SEMICONDUCTOR PACKAGE

(71) Applicant: SAMSUNG ELECTRONICS CO., LTD., Suwon-si (KR)

(72) Inventor: Keunyoung LEE, Suwon-si (KR)

(73) Assignee: SAMSUNG ELECTRONICS CO., LTD., Suwon-si (KR)

(21) Appl. No.: 19/284,123

(22) Filed: Jul. 29, 2025

(30) Foreign Application Priority Data
Jan. 14, 2025 (KR) 10-2025-0005683

(51) Int. Cl. H10W 70/65; H10B 80/00; H10W 70/60; H10W 90/00; H10W 90/24

(52) U.S. Cl. CPC H10W 70/65; H10B 80/00; H10W 70/611; H10W 90/00; H10W 90/24; H10W 90/724; H10W 90/752; H10W 90/754

(57) ABSTRACT

A semiconductor package may include a package substrate having upper and lower surfaces opposing each other, a control chip and a chip stack structure disposed on the upper surface of the package substrate, a first pad and a first pattern disposed on the lower surface of the package substrate and horizontally spaced apart from each other, and a dummy pattern disposed on the lower surface of the package substrate and interposed between the first pad and the first pattern, in which the dummy pattern is spaced apart from the first pad and the first pattern.

### CROSS-REFERENCE TO RELATED APPLICATIONS

This U.S. non-provisional patent application claims priority under 35 U.S.C. §119 to Korean Patent Application No. 10-2025-0005683 filed on January 14, 2025, in the Korean Intellectual Property Office, the entire contents of which are hereby incorporated by reference.

### BACKGROUND OF THE INVENTION

The inventive concept relates to a semiconductor package, and more specifically, relates to a semiconductor package including a test pad.

An integrated circuit chip may be realized in the form of a semiconductor package to be used in an electronic product. In a typical semiconductor package, a semiconductor chip may be mounted on a printed circuit board and may be electrically connected to the printed circuit board through bonding wires or bumps. Various techniques for reliability improvement, electrical characteristics improvement and miniaturization of semiconductor packages have been studied with development of the electronics industry.

### SUMMARY

An object of the inventive concept is to provide a semiconductor package that prevents defects due to electro-migration.

A semiconductor package according to some embodiments of the inventive concept may include a package substrate having upper and lower surfaces opposing each other, a control chip and a chip stack structure disposed on the upper surface of the package substrate, a first pad and a first pattern disposed on the lower surface of the package substrate and horizontally spaced apart from each other, and a dummy pattern disposed on the lower surface of the package substrate and interposed between the first pad and the first pattern, in which the dummy pattern is spaced apart from the first pad and the first pattern.

A semiconductor package according to some embodiments of the inventive concept may include a package substrate having upper and lower surfaces opposing each other, a control chip and a chip stack structure disposed on the upper surface of the package substrate, a first pad and a first pattern disposed on the lower surface of the package substrate, and a dummy pattern disposed between the first pad and the first pattern on the lower surface of the package substrate, in which the package substrate includes a lower insulating layer, a core layer disposed on the lower insulating layer, an upper insulating layer disposed on the core layer, and lower vias disposed in the lower insulating layer and respectively connected to the first pad and the first pattern. The control chip may include control pads and control connection terminals connecting the control pads and the package substrate, the chip stack structure may include a plurality of memory chips that are stacked in a vertical direction perpendicular to the upper surface of the package substrate and metal connection lines respectively connecting the memory chips and the package substrate, the dummy pattern may have a shape surrounding the first pad when viewed in a plan view, and the dummy pattern may be spaced from the first pad and the first pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram illustrating a schematic configuration of a semiconductor package according to some embodiments of the inventive concept.

FIG. 2 is a plan view illustrating a schematic configuration of a semiconductor package according to some embodiments of the inventive concept.

FIG. 3 is a cross-sectional view of a semiconductor package according to some embodiments of the inventive concept.

FIG. 4 is a plan view of a semiconductor package according to some embodiments of the inventive concept, illustrating a lower surface of the semiconductor package corresponding to portion ‘P’ of FIG. 3.

FIG. 5 is a cross-sectional view of a semiconductor package according to some embodiments of the inventive concept, and is an enlarged view of portion ‘P’ of FIG. 3.

FIGS. 6A through 8B are views illustrating a method of manufacturing a semiconductor package according to some embodiments of the inventive concept.

### DETAILED DESCRIPTION

Hereinafter, a semiconductor package and a manufacturing method thereof according to embodiments of the inventive concept will be described in detail with reference to the drawings.

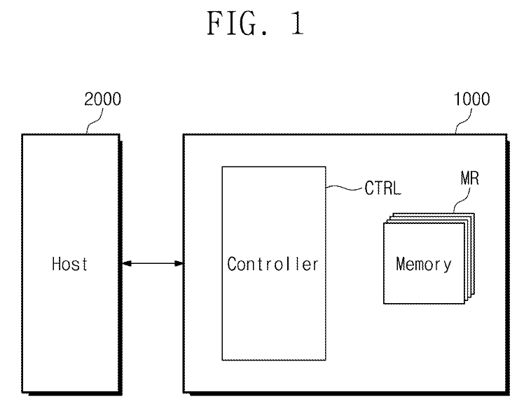

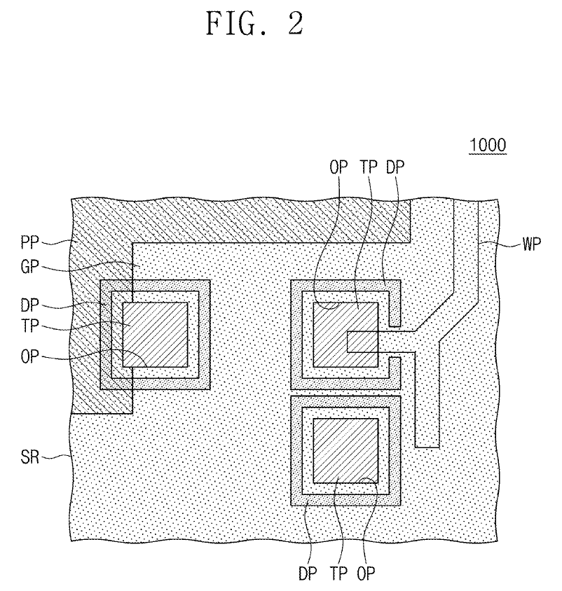

FIG. 1 is a block diagram illustrating a schematic configuration of a semiconductor package according to embodiments of the inventive concept. FIG. 2 is a plan view schematically illustrating a portion of a semiconductor package according to some embodiments of the inventive concept.

Referring to FIG. 1, a semiconductor package may be a universal flash storage package (UFS package) 1000. The universal flash storage package 1000 may store or read data in response to a read/write request from a host 2000. The host 2000 may be an external electronic device. The universal flash storage package 1000 may include a controller CTRL and a memory element MR. The controller CTRL may exchange signals with the host 2000. Here, signals between the controller CTRL and the host 2000 may include commands, addresses, and/or data. The controller CTRL may write data to the corresponding memory element MR or read data from the corresponding memory element MR in response to a command of the host 2000. The memory element MR may be a nonvolatile memory element. A plurality of memory elements MR may be provided. The plurality of memory elements MR may be NAND flash memories (hereinafter, NAND) having large capacity and high-speed storage capabilities. Alternatively, the memory elements MR may be a phase-change memory (PRAM), a magnetic memory (MRAM), a resistive memory (ReRAM), a ferromagnetic memory (FRAM), or an NOR flash memory.

Referring to FIG. 2, a semiconductor package 1000 may include a power pad PP, a ground pattern GP, a wiring pad WP, a test pad TP, and a dummy pattern DP. The ground pattern GP may be disposed in an region that does not vertically overlap the power pad PP, the wiring pad WP, the test pad TP, and the dummy pattern DP illustrated in FIG. 2. However, a person skilled in the art may appropriately arrange the position of the ground pattern GP as needed, and the inventive concept is not limited thereto.

A power voltage may be applied to the power pad PP, and a ground voltage may be applied to the ground pattern GP. A test voltage for testing memory chips mounted inside the semiconductor package 1000 may be applied to the test pad TP. The wiring pad WP may serve to provide electrical connections required for the power pad PP, the test pad TP, and the ground pattern GP. A person skilled in the art may design the wiring pad WP in various ways as needed, and the inventive concept is not limited thereto.

When viewed in a plan view, the dummy pattern DP may have a shape surrounding the test pad TP. The dummy pattern DP may be provided to be spaced apart from the test pad TP. The dummy pattern DP may not be applied with voltage. For example, the dummy pattern DP may be electrically floated. According to some embodiments, the dummy pattern DP may have a square ring shape surrounding the test pad TP. A shape of the dummy pattern DP may be formed in various ways by a person skilled in the art as needed, and the inventive concept is not limited thereto.

A solder resist layer SR including an opening OP may be disposed on the entire lower surface of the semiconductor package 1000. The solder resist layer SR may cover the power pad PP, the ground pattern GP, the wiring pad WP, and the dummy pattern DP. The opening OP may expose the test pad TP to the outside. That is, the opening OP may be disposed on an region vertically overlapping the test pad TP.

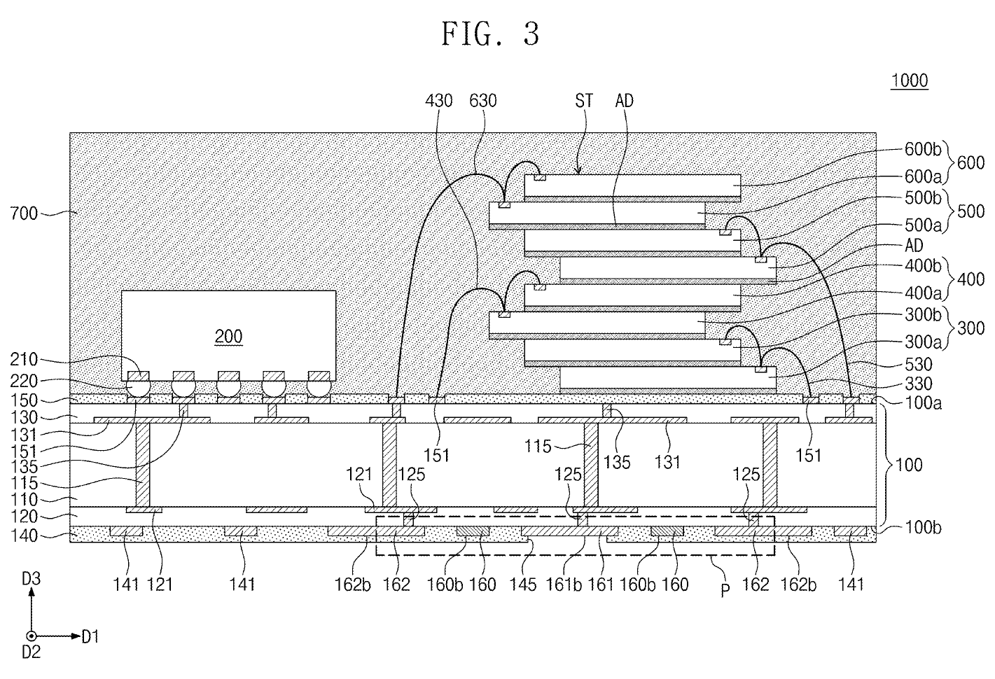

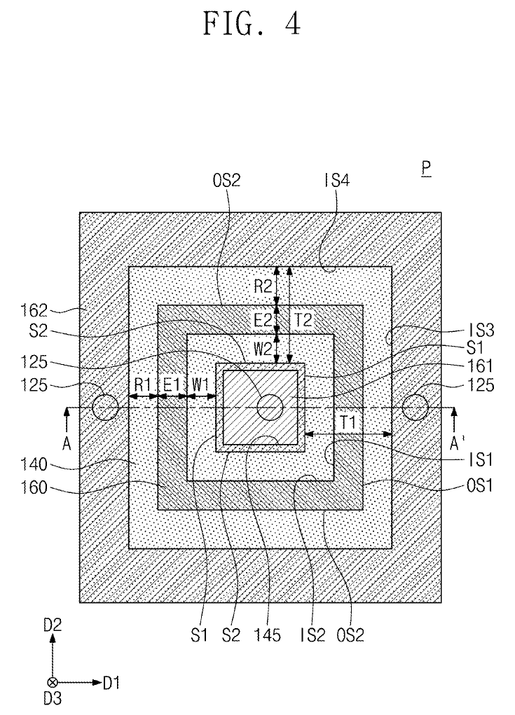

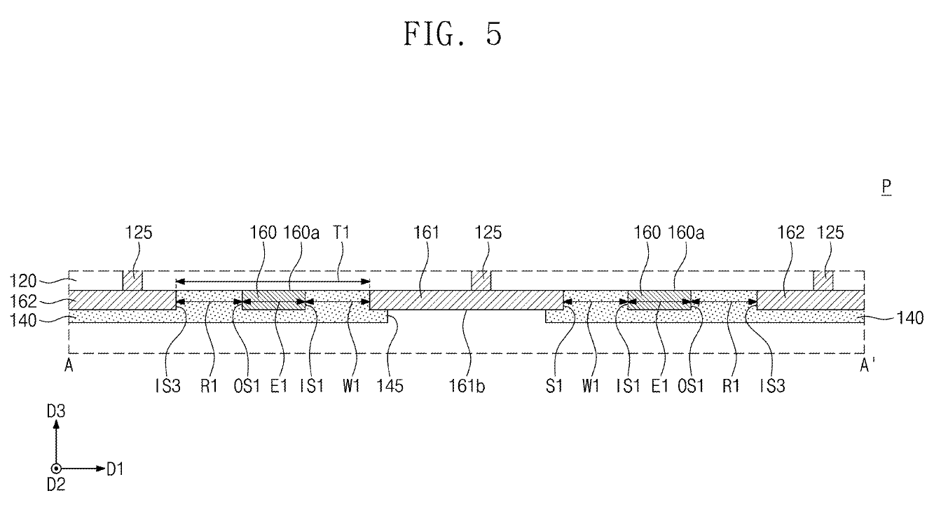

FIG. 3 is a cross-sectional view of a semiconductor package according to some embodiments of the inventive concept. FIG. 4 is a plan view of a semiconductor package according to some embodiments of the inventive concept, illustrating a lower surface of the semiconductor package corresponding to portion ‘P’ of FIG. 3. FIG. 5 is a cross-sectional view of a semiconductor package according to some embodiments of the inventive concept, and is an enlarged view of portion ‘P’ of FIG. 3.

Referring to FIGS. 3 to 5, a semiconductor package 1000 may include a package substrate 100, a lower solder resist layer 140, an upper solder resist layer 150, a control chip 200, a chip stack structure ST, and a molding layer 700.

According to some embodiments, the semiconductor package 1000 may be a multi-chip package (MCP) including different types of semiconductor chips. The semiconductor package 1000 may be a system in package (SIP) that stacks or arranges a plurality of semiconductor chips in one package to have an independent function.

The package substrate 100 may be, for example, a printed circuit board (PCB). The package substrate 100 may include an upper surface 100a and a lower surface 100b that face each other in a third direction D3. In the present specification, a first direction D1 and a second direction D2 may be directions that are parallel to the upper surface 100a of the package substrate 100 and intersect each other. The third direction D3 may be a vertical direction D3 that is perpendicular to the upper surface 100a of the package substrate 100. For example, the first to third directions D1, D2, and D3 may be directions that are orthogonal to each other.

The package substrate 100 may include a core layer 110, a lower insulating layer 120, and an upper insulating layer 130. The lower insulating layer 120 may be arranged below the core layer 110. The lower insulating layer 120 may be disposed adjacent to the lower surface 100b of the package substrate 100. The upper insulating layer 130 may be disposed above the core layer 110. The upper insulating layer 130 may be arranged adjacent to the upper surface 100a of the package substrate 100. The core layer 110 may be interposed between the lower insulating layer 120 and the upper insulating layer 130.

The core layer 110, the lower insulating layer 120, and the upper insulating layer 130 may include, for example, a composite material in which glass fiber fabric is impregnated with epoxy resin.

A core penetration via 115 may be provided inside the core layer 110. The core penetration via 115 may penetrate the core layer 110 in the third direction D3.

First upper wirings 131 and upper vias 135 may be provided in the upper insulating layer 130. The upper vias 135 and the first upper wirings 131 may be electrically connected to the core penetration via 115.

Second upper wirings 151 may be provided on the upper surface 100a of the package substrate 100. The second upper wirings 151 may be provided on the upper insulating layer 130. The second upper wirings 151 may be electrically connected to the upper vias 135.

The upper solder resist layer 150 may be provided on the upper surface 100a of the package substrate 100. The upper solder resist layer 150 may be provided on the upper insulating layer 130. The upper solder resist layer 150 may be interposed between the second upper wirings 151. The upper solder resist layer 150 may not cover upper surfaces of the second upper wirings 151 and may expose the upper surfaces of the second upper wirings 151. The upper solder resist layer 150 may include, for example, an epoxy-based insulating resin.

The core penetration via 115, the first upper wirings 131, the upper vias 135, and the second upper wirings 151 may include metal, for example, copper (Cu).

The control chip 200 may be provided on the package substrate 100. Control pads 210 may be provided in the control chip 200 adjacent to a lower surface of the control chip 200. Control connection terminals 220 may be provided on lower surfaces of the control pads 210, respectively. Each of the control connection terminals 220 may be connected to a corresponding second upper wirings 151, respectively. The control chip 200 may be electrically connected to the package substrate 100 through the control pads 210 and the control connection terminals 220. The control chip 200 may be the controller CTRL described with reference to FIG. 1.

The control pads 210 may include a metal, for example, copper (Cu). The control connection terminals 220 may include solder balls or solder bumps. The control connection terminals 220 may be an alloy including at least one of tin (Sn), silver (Ag), copper (Cu), nickel (Ni), bismuth (Bi), indium (In), antimony (Sb), or cerium (Ce).

The chip stack structure ST may be provided on a package substrate 100. The chip stack structure ST may be disposed to be spaced apart from the control chip 200 in the first direction D1. The chip stack structure ST may include first to fourth memory chips 300, 400, 500, and 600 sequentially stacked on the package substrate 100. In FIG. 3, the number of chips included in the first to fourth memory chips 300, 400, 500, and 600 is indicated as 8, but the number of chips included in the chip stack structure ST may be variously changed. The first to fourth memory chips 300, 400, 500, and 600 may include a non-volatile memory device such as a NAND flash memory. Each of first memory chips 300a and 300b may include the same type of memory chip. Similarly, each of second memory chips 400a and 400b, third memory chips 500a and 500b, and fourth memory chips 600a and 600b may include the same type of memory chip. The first memory chips 300a and 300b may be connected to each other by bonding wires and may share the same channel. The second memory chips 400a and 400b, the third memory chips 500a and 500b, and the fourth memory chips 600a and 600b may also be connected to each other by bonding wires like the first memory chips 300a and 300b and may share the same channel. The first memory chips 300a and 300b may be sequentially stacked on the package substrate 100 using adhesive layers AD. The second memory chips 400a and 400b, the third memory chips 500a and 500b, and the fourth memory chips 600a and 600b may be sequentially attached on the first memory chips 300a and 300b using adhesive layers AD. Specifically, the first memory chips 300a and 300b and the second memory chip 400a of the lowest layer may be stacked in a cascade structure. The second memory chips 400a and 400b and the third memory chip 500a of the lowest layer may be stacked in a cascade structure. The third memory chips 500a and 500b and the fourth memory chip 600a of the lowest layer may be stacked in a cascade structure. The first to fourth memory chips 300, 400, 500, and 600 included in the chip stack structure ST may be stacked in a cascade structure while intersecting in a direction toward the control chip 200 (e.g., in a direction opposite to the first direction D1) or in a direction away from the control chip 200 (e.g., in the first direction D1). Each of the first to fourth memory chips 300, 400, 500, and 600 may be electrically connected to each of third substrate pads 126 by each of first to fourth metal connection lines 330, 430, 530, and 630. Each of the first to fourth metal connection lines 330, 430, 530, and 630 may include, for example, a bonding wire. The chip stack structure ST may be the memory element MR described with reference to FIG. 1.

The molding layer 700 may be provided on the package substrate 100. The molding layer 700 may cover the upper solder resist layer 150, the second upper wirings 151, the chip stack structure ST, and the control chip 200. The molding layer 700 may fill a space between the control connection terminals 220. The molding layer 700 may include an insulating material. The molding layer 700 may include an insulating material, such as an epoxy molding compound (EMC), for example.

First lower wirings 121 and lower vias 125 may be provided in the lower insulating layer 120. The lower vias 125 and the first lower wirings 121 may be electrically connected to the core penetration vias 115.

Second lower wirings 141 may be provided on the lower surface 100b of the package substrate 100. The second lower wirings 141 may be provided on the lower insulating layer 120. The second lower wirings 141 may be electrically connected to the lower vias 125.

The first lower wirings 121, the lower vias 125, and the second lower wirings 141 may include metal, for example, copper (Cu).

The lower solder resist layer 140 may be provided on the lower surface 100b of the package substrate 100. The lower solder resist layer 140 may be provided on the lower insulating layer 120. The lower solder resist layer 140 may cover the second lower wirings 141 and fill a space between the second lower wirings 141.

A first pad 161, a first pattern 162, and a dummy pattern 160 may be provided on the lower surface 100b of the package substrate 100. The first pad 161, the first pattern 162, and the dummy pattern 160 may be disposed on a lower insulating layer 120 and may be disposed to be horizontally spaced apart from each other. For example, the first pad 161, the first pattern 162, and the dummy pattern 160 may be spaced apart from each other in a horizontal direction (the first direction D1 and/or the second direction D2) parallel to the upper surface 100a of the package substrate 100. The dummy pattern 160 may be interposed between the first pad 161 and the first pattern 162. The dummy pattern 160 may be spaced apart from the first pad 161 and the first pattern 162 in a horizontal direction (first direction D1 and/or second direction D2) between the first pad 161 and the first pattern 162.

When viewed in a plan view, the dummy pattern 160 may have a shape surrounding the first pad 161. According to some embodiments, the dummy pattern 160 may have a square ring shape surrounding the first pad 161 having a square shape. That is, the dummy pattern 160 may have a ring shape surrounding the first pad 161. When viewed in a plan view, the first pattern 162 may have a shape surrounding the dummy pattern 160. According to some embodiments, in a region where the first pad 161 and the first pattern 162 horizontally overlap, the dummy pattern 160 may be interposed between the first pad 161 and the first pattern 162.

A lower surface 161b of the first pad 161, a lower surface 162b of the first pattern 162, and a lower surface 160b of the dummy pattern 160 may be coplanar with each other. For example, the lower surface 161b of the first pad 161, the lower surface 162b of the first pattern 162, and the lower surface 160b of the dummy pattern 160 may have substantially the same distance measured from the lower surface 100b of the package substrate 100 in the opposite direction in the third direction D3.

As used herein, the expression “substantially the same distance” may refer to having the same distance relative to other distances compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ± 1%, ± 5% , or ± 10% of the actual value stated, and other suitable tolerances.

The first pad 161, the first pattern 162, and the dummy pattern 160 may include a metal, and may include, for example, copper (Cu).

The first pad 161, the first pattern 162, and the dummy pattern 160 may be the test pad TP, the ground pattern GP, and the dummy pattern DP, respectively, as described with reference to FIG. 2.

The lower solder resist layer 140 may cover the first pattern 162 and the dummy pattern 160. The lower solder resist layer 140 may include an opening 145. The opening 145 may expose at least a portion of the lower surface 161b of the first pad 161. That is, the lower solder resist layer 140 may not cover the first pad 161 or may cover only a portion of the first pad 161. The lower solder resist layer 140 may fill gaps between the first pad 161, the first pattern 162, and the dummy pattern 160 that are spaced apart from each other in the horizontal direction D1 or D2. That is, the lower solder resist layer 140 may be interposed between the first pad 161 and the dummy pattern 160, and between the dummy pattern 160 and the first pattern 162. The lower solder resist layer 140 may include, for example, an epoxy-based insulating resin. The lower solder resist layer 140 may be the solder resist layer SR described with reference to FIG. 2.

The first pad 161 may have a first sidewall S1 perpendicular to the first direction D1 and a second sidewall S2 perpendicular to the second direction D2. That is, the first sidewall S1 of the first pad 161 may extend parallel to the second direction D2, and the second sidewall S2 of the first pad 161 may extend parallel to the first direction D1.

The dummy pattern 160 may include inner sidewalls IS1 and IS2 facing the first pad 161. The inner sidewalls IS1 and IS2 of the dummy pattern 160 may include a first inner sidewall IS1 perpendicular to the first direction D1 and a second inner sidewall IS2 perpendicular to the second direction D2. That is, the first inner sidewall IS1 of the dummy pattern 160 may extend parallel to the second direction D2, and the second inner sidewall IS2 of the dummy pattern 160 may extend parallel to the first direction D1.

The first sidewall S1 of the first pad 161 and the first inner sidewall IS1 of the dummy pattern 160 may be spaced apart by a first inner distance W1 in the first direction D1. The first inner distance W1 may mean a length measured in the first direction D1 from the first sidewall S1 of the first pad 161 to the first inner sidewall IS1 of the dummy pattern 160. According to some embodiments, the first inner distance W1 may range from 5 to 50 um. For example, the first inner distance W1 may range from 10 to 30 um.

The second sidewall S2 of the first pad 161 and the second inner sidewall IS2 of the dummy pattern 160 may be spaced apart by a second inner distance W2 in the second direction D2. The second inner distance W2 may mean a length measured in the second direction D2 from the second sidewall S2 of the first pad 161 to the second inner sidewall IS2 of the dummy pattern 160. According to some embodiments, the second inner distance W2 may range from 5 to 50 um. For example, the second inner distance W2 may range from 10 to 30 um.

The dummy pattern 160 may have outer sidewalls OS1 and OS2 facing the first pattern 162. The outer sidewalls OS1 and OS2 of the dummy pattern 160 may include a first outer sidewall OS1 facing the first inner sidewall IS1 in the first direction D1 and a second outer sidewall OS2 facing the second inner sidewall IS2 in the second direction D2. The first outer sidewall OS1 and the second outer sidewall OS2 of the dummy pattern 160 may face the first pattern 162. The first outer sidewall OS1 of the dummy pattern 160 may be perpendicular to the first direction D1. The second outer sidewall OS2 of the dummy pattern 160 may be perpendicular to the second direction D2. That is, the first outer sidewall OS1 of the dummy pattern 160 may extend parallel to the second direction D2, and the second outer sidewall OS2 of the dummy pattern 160 may extend parallel to the first direction D1.

The dummy pattern 160 may have a first width E1 in the first direction D1. The first width E1 may be a distance measured in the first direction D1 from the first inner sidewall IS1 to the first outer sidewall OS1 of the dummy pattern 160. In some embodiments, the first width E1 may range from 5 to 50 um. For example, the first width E1 may range from 10 to 30 um.

The dummy pattern 160 may have a second width E2 in the second direction D2. The second width E2 may be a distance measured in the second direction D2 from the second inner sidewall IS2 to the second outer sidewall OS2 of the dummy pattern 160. In some embodiments, the second width E2 may range from 5 to 50 um. For example, the second width E2 may range from 10 to 30 um.

The first pattern 162 may have inner sidewalls IS3 and IS4 facing the dummy pattern 160 and the first pad 161. The inner sidewalls IS3 and IS4 of the first pattern 162 may include a first inner sidewall IS3 perpendicular to the first direction D1 and a second inner sidewall IS4 perpendicular to the second direction D2. That is, the first inner sidewall IS3 of the first pattern 162 may extend parallel to the second direction D2, and the second inner sidewall IS4 of the first pattern 162 may extend parallel to the first direction D1.

The first outer sidewall OS1 of the dummy pattern 160 and the first inner sidewall IS3 of the first pattern 162 may be spaced apart from each other by a first outer distance R1 in the first direction D1. The first outer distance R1 may mean a length measured in the first direction D1 from the first outer sidewall OS1 of the dummy pattern 160 to the first inner sidewall IS3 of the first pattern 162. According to some embodiments, the first outer distance R1 may range from 5 to 50 um. For example, the first outer distance R1 may range from 10 to 30 um.

The second outer sidewall OS2 of the dummy pattern 160 and the second inner sidewall IS2 of the first pattern 162 may be spaced apart from each other by a second outer distance R2 in the second direction D2. The second outer distance R2 may refer to a length measured in the second direction D2 from the second outer sidewall OS2 of the dummy pattern 160 to the second inner sidewall IS2 of the first pattern 162. In some embodiments, the second outer distance R2 may range from 5 to 50 um. For example, the second outer distance R2 may range from 10 to 30 um.

The first sidewall S1 of the first pad 161 and the first inner sidewall IS3 of the first pattern 162 may be spaced apart from each other by a first total distance T1 in the first direction D1. The first total distance T1 may mean a length measured in the first direction D1 from the first sidewall S1 of the first pad 161 to the first inner sidewall IS3 of the first pattern 162. According to some embodiments, the first total distance T1 may range from 15 to 150 um. For example, the first total distance T1 may range from 30 to 90 um.

The second sidewall S2 of the first pad 161 and the second inner sidewall IS4 of the first pattern 162 may be spaced apart from each other by a second total distance T2 in the second direction D2. The second total distance T2 may mean a length measured in the second direction D2 from the second sidewall S2 of the first pad 161 to the second inner sidewall IS4 of the first pattern 162. In some embodiments, the second total distance T2 may range from 15 to 150 um. For example, the second total distance T2 may range from 30 to 90 um.

As one exemplary measurement method of the aforementioned distances, a “distance” between two targeted surfaces may mean an average value of shortest distances between the two targeted surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

The first pad 161 and the first pattern 162 may be electrically connected to the corresponding lower via 125 , respectively. An upper surface 160aof the dummy pattern 160 may be entirely covered by the lower solder resist layer 140. That is, the dummy pattern 160 may not be connected to the lower via 125. For example, the dummy pattern 160 may be electrically floating.

Although the first pad 161 is illustrated as having a rectangular shape when viewed in a plan view, the shape of the first pad 161 may be appropriately changed as needed by a person skilled in the art, and the inventive concept is not limited thereto. In addition, the dummy pattern 160 may be changed by a person skilled in the art to have a shape surrounding the first pad 161 instead of a square ring shape as shown, as needed, and the inventive concept is not limited thereto.

When there is no dummy pattern 160 between the first pad 161 and the first pattern 162, a defect may occur during the process of testing the memory device. For example, a test voltage may be applied to the first pad 161 and a ground voltage (i.e., 0 V) may be applied to the first pattern 162 to test a memory device mounted on a semiconductor package 1000. In this case, an electric field may be generated from the first pad 161 to the first pattern 162, and a defect may occur due to electro-migration. However, according to an embodiment of the inventive concept, the dummy pattern 160 may be disposed between the first pad 161 and the first pattern 162, to prevent an electric field from being formed from the first pad 161 to the first pattern 162. That is, the dummy pattern 160 that acts as a barrier between the first pad 161 and the first pattern 162 may be provided, and thus an electric field may be prevented from being formed from the first pad 161 to the first pattern 162. Accordingly, defects due to electro-migration may be prevented at the source. In addition, in the conventional case, the gap between the first pad 161 and the first pattern 162 is formed at a level exceeding 150 um, thereby reducing probability of defects due to the aforementioned electro-migration. However, according to the inventive concept, the first and second inner distances W1 and W2 between the first pad 161 and the dummy pattern 160, the first and second widths E1 and E2 of the dummy pattern 160, the first and second outer distances R1 and R2 between the dummy pattern 160 and the first pattern 162, and the first and second total distances T1 and T2 between the first pad 161 and the first pattern 162 may be formed to a level smaller than 150 um. Accordingly, the semiconductor package according to the inventive concept has an advantageous effect of easily securing a design space compared to the conventional one while reliably preventing defects due to the electro-migration.

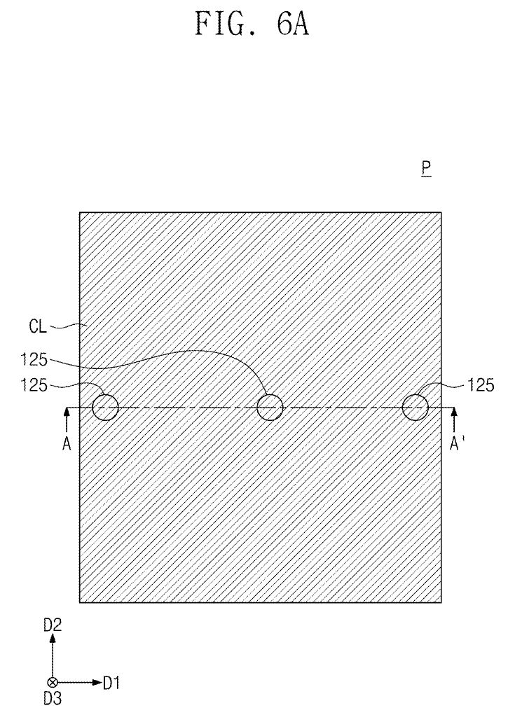

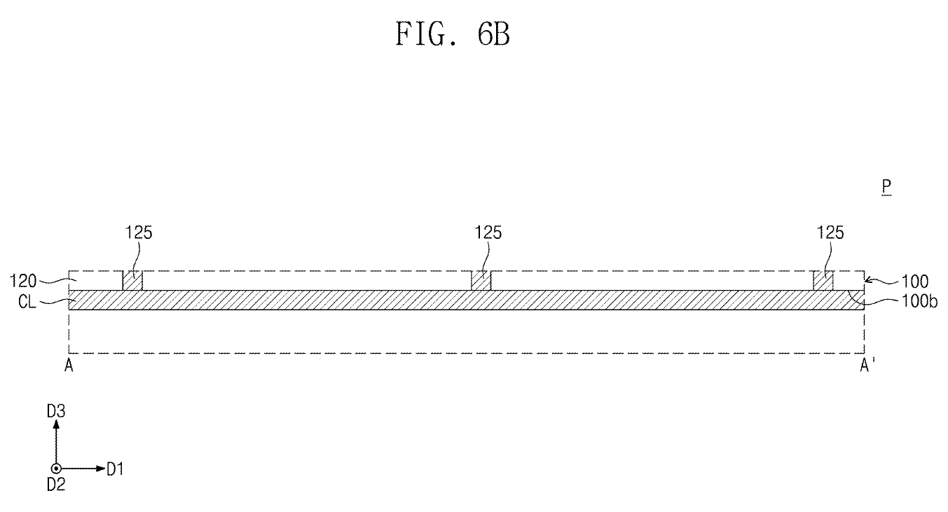

FIGS. 6A through 8B are drawings illustrating a method of manufacturing a semiconductor package according to some embodiments of the inventive concept. Specifically, FIGS. 6A, 7A, and 8A are plan views illustrating a lower surface of a semiconductor package corresponding to portion ‘P’ of FIG. 3. FIGS. 6B, 7B, and 8B are enlarged views of portion ‘P’ portion of FIG. 3, and are cross-sectional views corresponding to line A-A' of FIGS. 6A, 7A, and 8A, respectively. For simplicity of explanation, any content overlapping with the above will be omitted.

Referring to FIGS. 3, 6A, and 6B, a package substrate 100 may be provided. The package substrate 100 may include a core layer 110, a lower insulating layer 120, an upper insulating layer 130, a core penetration via 115, first upper wirings 131, upper vias 135, first lower wirings 121, and lower vias 125 described with reference to FIGS. 3 to 5.

A conductive layer CL may be formed on a lower surface 100b of the package substrate 100. The conductive layer CL may include a metal, for example, copper (Cu). The conductive layer CL may be formed using a layer forming technique, such as chemical vapor deposition (CVD), physical vapor deposition (PVD), and so on.

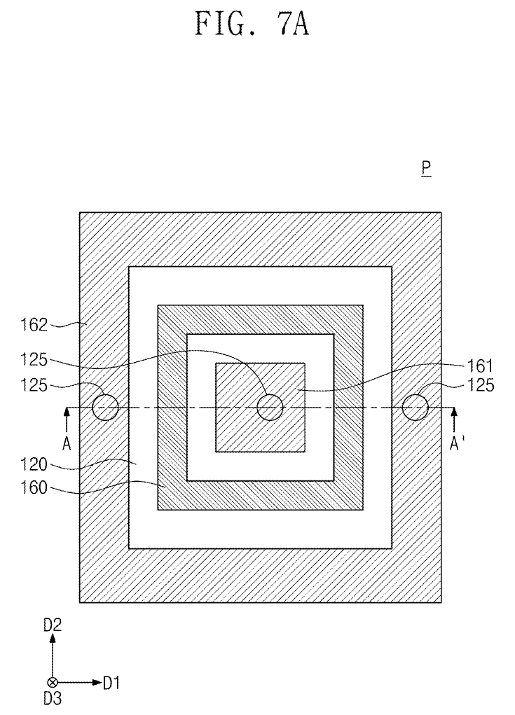

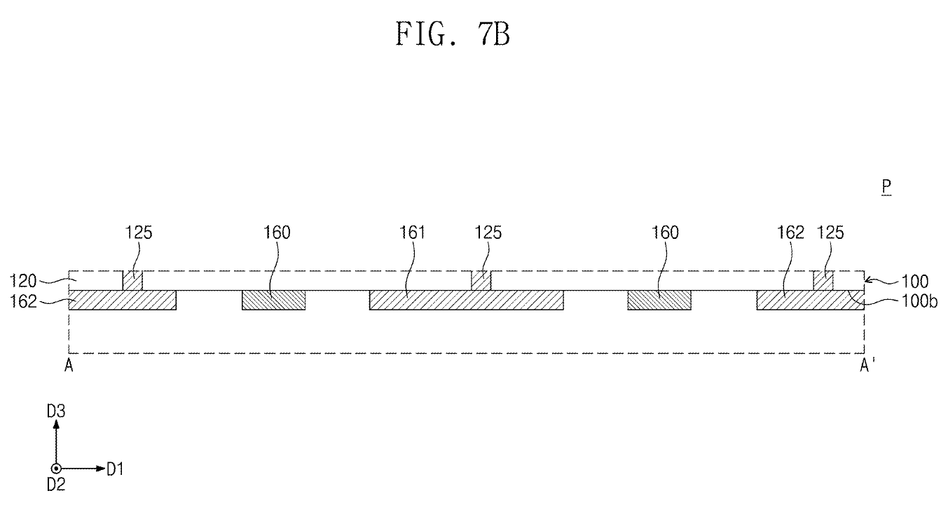

Referring to FIG. 3, FIG. 7A, and FIG. 7B, second lower wirings 141, a first pad 161, a first pattern 162, and a dummy pattern 160 may be formed on the lower surface 100b of the package substrate 100. Forming the second lower wirings 141, the first pad 161, the first pattern 162, and the dummy pattern 160 may be performed through a patterning process. The patterning process may include, for example, forming a mask pattern (not shown) on the conductive layer CL, etching the conductive layer CL using the mask pattern as an etching mask, and removing the mask pattern.

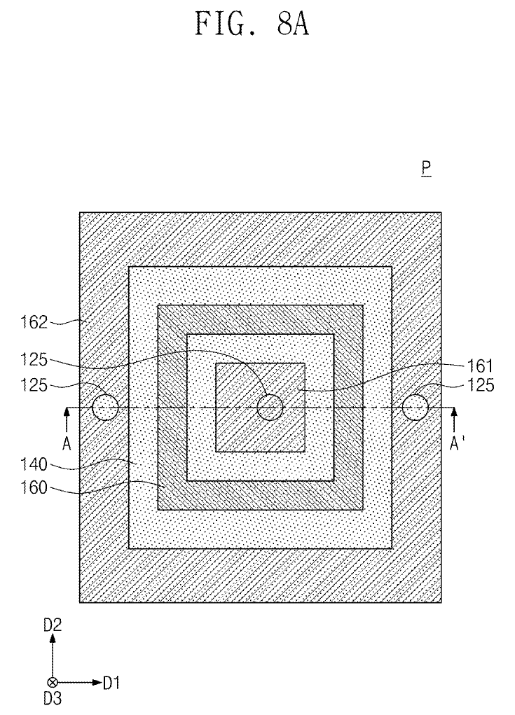

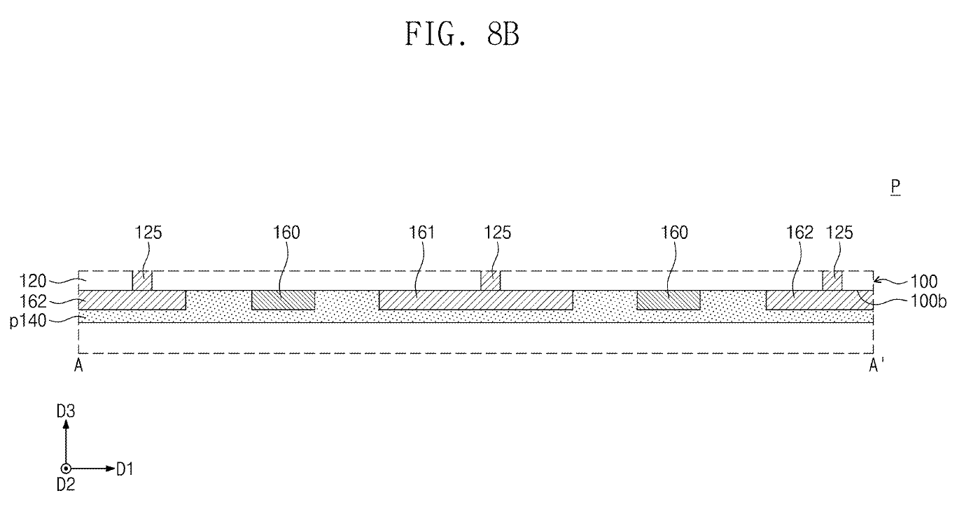

Referring to FIG. 3, FIG. 8A, and FIG. 8B, a preliminary lower solder resist layer p140 may be formed on the lower surface 100b of the package substrate 100. The preliminary lower solder resist layer p140 may cover the entire lower surface 100b of the package substrate 100. The preliminary lower solder resist layer p140 may cover the second lower wirings 141, the first pad 161, the first pattern 162, and the dummy pattern 160. Forming the preliminary lower solder resist layer p140 may include, for example, coating a solder resist material on the lower surface 100b of the package substrate 100, and performing exposure, development, and curing processes on the solder resist material.

Referring again to FIGS. 3 to 5, a portion of the preliminary lower solder resist layer p140 may be removed to form a lower solder resist layer 140 including an opening OP. The opening OP may expose at least a portion of a lower surface 161b of the first pad 161.

Subsequently, second upper wirings 151 and an upper solder resist layer 150 may be formed on an upper surface 100a of the package substrate 100. Forming the upper solder resist layer 150 may include substantially the same method as forming the lower solder resist layer 140 described above.

Then, a control chip 200 and chip stack structure ST may be mounted on the package substrate 100. In addition, a molding layer 700 may be formed on the package substrate 100. Accordingly, a semiconductor package 1000 according to an embodiment of the inventive concept may be formed.

According to the inventive concept, the dummy pattern may be disposed between the first pad and the first pattern for testing the memory chip. Accordingly, the dummy pattern may prevent the electric field from being formed between the first pad and the first pattern to which different voltages are applied. Therefore, the defect due to the electro-migration between the first pad and the first pattern may be fundamentally blocked. In addition, the gap between the first pad and the first pattern may be formed at the smaller level than before, thereby easily securing the design space.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a package substrate having upper and lower surfaces opposing each other;
a control chip and a chip stack structure disposed on the upper surface of the package substrate;
a first pad and a first pattern disposed on the lower surface of the package substrate and spaced apart from each other; and
a dummy pattern disposed on the lower surface of the package substrate and interposed between the first pad and the first pattern,
wherein the dummy pattern is spaced apart from the first pad and the first pattern.

2. The semiconductor package of claim 1, wherein the dummy pattern has a ring shape surrounding the first pad, when viewed in a plan view.

3. The semiconductor package of claim 1, wherein the dummy pattern includes inner sidewalls facing the first pad,
wherein the inner sidewalls of the dummy pattern include a first inner sidewall perpendicular to a first direction parallel to the upper surface of the package substrate,
wherein the first pad includes a first sidewall perpendicular to the first direction,
wherein the first sidewall of the first pad and the first inner sidewall of the dummy pattern are spaced apart from each other by a first inner distance in the first direction, and
wherein the first inner distance ranges from 5 to 50 um.

4. The semiconductor package of claim 3, wherein the first pad includes a second sidewall perpendicular to a second direction that is parallel to the upper surface of the package substrate and intersects the first direction,
wherein the inner sidewalls of the dummy pattern include a second inner sidewall that is perpendicular to the second direction,
wherein the second sidewall of the first pad and the second inner sidewall of the dummy pattern are spaced apart from each other by a second inner distance in the second direction, and
wherein the second inner distance ranges from 5 to 50 um.

5. The semiconductor package of claim 1, wherein the dummy pattern includes inner sidewalls facing the first pad and outer sidewalls facing the first pattern,
wherein the inner sidewalls of the dummy pattern include a first inner sidewall perpendicular to a first direction parallel to the upper surface of the package substrate,
wherein the outer sidewalls of the dummy pattern include a first outer sidewall perpendicular to the first direction,
wherein the dummy pattern has a first width in the first direction from the first inner sidewall to the first outer sidewall, and
wherein the first width ranges from 5 to 50 um.

6. The semiconductor package of claim 5, wherein the inner sidewalls of the dummy pattern include a second inner sidewall perpendicular to a second direction that is parallel to the upper surface of the package substrate and intersects the first direction,
wherein the outer sidewalls of the dummy pattern include a second outer sidewall that is perpendicular to the second direction,
wherein the dummy pattern has a second width in the second direction from the second inner sidewall to the second outer sidewall, and
wherein the second width ranges from 5 to 50 um.

7. The semiconductor package of claim 1, wherein the dummy pattern includes outer sidewalls facing the first pattern,
wherein the outer sidewalls of the dummy pattern include a first outer sidewall perpendicular to a first direction parallel to the upper surface of the package substrate,
wherein the first pattern includes inner sidewalls facing the dummy pattern,
wherein the inner sidewalls of the first pattern include a first inner sidewall perpendicular to the first direction,
wherein the first outer sidewall of the dummy pattern and the first inner sidewall of the first pattern are spaced apart from each other by a first outer distance in the first direction, and
wherein the first outer distance ranges from 5 to 50 um.

8. The semiconductor package of claim 7, wherein the outer sidewalls of the dummy pattern include a second outer sidewall perpendicular to a second direction that is parallel to the upper surface of the package substrate and intersects the first direction,
wherein the inner sidewalls of the first pattern include a second inner sidewall that is perpendicular to the second direction,
wherein the second outer sidewall of the dummy pattern and the second inner sidewall of the first pattern are spaced apart from each other by a second outer distance in the second direction, and
wherein the second outer distance ranges from 5 to 50 um.

9. The semiconductor package of claim 1, wherein the first pad includes a first sidewall perpendicular to a first direction parallel to the upper surface of the package substrate,
wherein the first pattern includes inner sidewalls facing the dummy pattern,
wherein the inner sidewalls of the first pattern include a first inner sidewall perpendicular to the first direction,
wherein the first sidewall of the first pad and the first inner sidewall of the first pattern are spaced apart from each other by a first total distance in the first direction, and
wherein the first total distance ranges from 15 to 150 um.

10. The semiconductor package of claim 9, wherein the first pad includes a second sidewall perpendicular to a second direction that is parallel to the upper surface of the package substrate and intersects the first direction,
wherein the inner sidewalls of the first pattern include a second inner sidewall that is perpendicular to the second direction,
wherein the second sidewall of the first pad and the second inner sidewall of the first pattern are spaced apart from each other by a second total distance in the second direction, and
wherein the second total distance ranges from 15 to 150 um.

11. The semiconductor package of claim 1, further comprising a lower solder resist layer disposed on the lower surface of the package substrate,
wherein the lower solder resist layer includes an opening, and
wherein the opening exposes at least a portion of a lower surface of the first pad.

12. The semiconductor package of claim 1, further comprising a lower insulating layer adjacent to the lower surface of the package substrate,
wherein an upper surface of the dummy pattern is entirely covered by the lower insulating layer.

13. The semiconductor package of claim 12, further comprising lower vias disposed in the lower insulating layer,
wherein the lower vias are connected to the first pad and the first pattern, respectively.

14. A semiconductor package comprising:
a package substrate having upper and lower surfaces opposing each other;
a control chip and a chip stack structure disposed on the upper surface of the package substrate;
a first pad and a first pattern disposed on the lower surface of the package substrate; and
a dummy pattern disposed between the first pad and the first pattern on the lower surface of the package substrate,
wherein the package substrate includes:
a lower insulating layer;
a core layer disposed on the lower insulating layer;
an upper insulating layer disposed on the core layer; and
lower vias disposed in the lower insulating layer and respectively connected to the first pad and the first pattern,
wherein the control chip includes control pads and control connection terminals connecting the control pads and the package substrate,
wherein the chip stack structure includes a plurality of memory chips that are stacked in a vertical direction perpendicular to the upper surface of the package substrate and metal connection lines respectively connecting the memory chips and the package substrate,
wherein the dummy pattern has a shape surrounding the first pad when viewed in a plan view, and
wherein the dummy pattern is spaced from the first pad and the first pattern.

15. The semiconductor package of claim 14, wherein the dummy pattern includes inner sidewalls facing the first pad,
wherein the inner sidewalls of the dummy pattern include a first inner sidewall perpendicular to a first direction parallel to the upper surface of the package substrate,
wherein the first pad includes a first sidewall perpendicular to the first direction,
wherein the first sidewall of the first pad and the first inner sidewall of the dummy pattern are spaced apart from each other by a first inner distance in the first direction, and
wherein the first inner distance ranges from 5 to 50 um.

16. The semiconductor package of claim 14, wherein the dummy pattern includes inner sidewalls facing the first pad and outer sidewalls facing the first pattern,
wherein the inner sidewalls of the dummy pattern include a first inner sidewall perpendicular to a first direction parallel to the upper surface of the package substrate,
wherein the outer sidewalls of the dummy pattern include a first outer sidewall perpendicular to the first direction,
wherein the dummy pattern has a first width in the first direction from the first inner sidewall to the first outer sidewall, and
wherein the first width ranges from 5 to 50 um.

17. The semiconductor package of claim 14, wherein the dummy pattern includes outer sidewalls facing the first pattern,
wherein the outer sidewalls of the dummy pattern include a first outer sidewall perpendicular to a first direction parallel to the upper surface of the package substrate,
wherein the first pattern includes inner sidewalls facing the dummy pattern,
wherein the inner sidewalls of the first pattern include a first inner sidewall perpendicular to the first direction,
wherein the first outer sidewall of the dummy pattern and the first inner sidewall of the first pattern are spaced apart from each other by a first outer distance in the first direction, and
wherein the first outer distance ranges from 5 to 50 um.

18. The semiconductor package of claim 14, wherein the first pad includes a first sidewall perpendicular to a first direction parallel to the upper surface of the package substrate,
wherein the first pattern includes inner sidewalls facing the dummy pattern,
wherein the inner sidewalls of the first pattern include a first inner sidewall perpendicular to the first direction,
wherein the first sidewall of the first pad and the first inner sidewall of the first pattern are spaced apart from each other by a first total distance in the first direction, and
wherein the first total distance ranges from 15 to 150 um.

19. The semiconductor package of claim 14, further comprising a lower solder resist layer disposed on the lower surface of the package substrate,
wherein the lower solder resist layer includes an opening, and
wherein the opening exposes at least a portion of a lower surface of the first pad.

20. The semiconductor package of claim 14, wherein an upper surface of the dummy pattern is entirely covered by the lower insulating layer.
